(19) United States
(12) Patent Application Publication
(10) Pub. No.: US 2026/0164577 A1
(43) Pub. Date: Jun. 11, 2026

(54) COVER PLATE AND DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Yanqiang DUAN, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 18/569,208

(22) PCT Filed: Nov. 10, 2023
(86) PCT No.: PCT/CN2023/131030

§ 371 Date: Dec. 11, 2023

(30) Foreign Application Priority Data
Nov. 3, 2023 (CN) 202311475760.3

(51) Int. Cl. H05K 5/03

(52) U.S. Cl. CPC H05K 5/03

(57) ABSTRACT

A cover plate and a display device are provided. The cover plate is attached to a display panel, the cover plate includes a first portion, and the first portion is used for covering at least a part on a front side of a bending portion. A side of the first portion facing the display panel is a first curved surface. In a first direction, a curvature radius of any point of the first curved surface is greater than or equal to 300 mm, the first curved surface covers at least a middle area of the bending portion, and the first direction is a direction of a long axis of the bending portion.

### TECHNICAL FIELD

The present application relates to the field of display technologies, and particularly to a cover plate and a display device.

### BACKGROUND

With a display module, on the one hand, a binding portion of a display panel needs to be bent to back of the display panel through a bending portion, and the bending portion is affected by bending stress in vertical bending direction. On the other hand, as a full-curved cover plate is assembled on the display panel, the bending portion of the display panel is affected by shape of the full-curved cover plate to bend along the bending direction of the full-curved cover plate. The bending portion is further affected by the bending stress in the bending direction of the full-curved cover plate. Bending central axes of the bending stresses in above directions are perpendicular to each other, so that an arc top (at elliptical circle) of the bending portion is inclined to CG side of the cover plate (as shown in FIG. 1). However, because an area of the full-curved cover plate with a small curvature radius corresponds to the bending portion, the bending radius at the arc top becomes locally less and the stress becomes greater, thereby causing breakage of wirings at the arc top.

### SUMMARY

The embodiments of the present application provide a cover plate and a display device, which can reduce the risk of breakage of wirings in a bending area of a display panel.

The embodiments of the present application provide a cover plate to attach to a display panel, the display panel includes a display main body, a bending portion, and a binding portion; the binding portion is provided on a back of the display main body through the bending portion;

the cover plate includes a first portion provided to cover at least a part on a front side of the bending portion; and a side of the first portion facing the display panel is a first curved surface; wherein a curvature radius of any point of the first curved surface is greater than or equal to 300 mm in a first direction, and the first curved surface covers at least a middle area of the bending portion, and the first direction is a direction of a long axis of the bending portion.

In some embodiments of the present application, a curvature radius of the first curved surface is constant in the first direction, and the first portion is provided to cover the bending portion entirely.

In some embodiments of the present application, the cover plate further includes a second portion connected to opposite sides of the first portion in the first direction, a side of the second portion facing the display panel is a second curved surface, the second curved surface is connected to the first curved surface, wherein the maximum curvature radius of the second curved surface is less than or equal to the curvature radius of the first curved surface in the first direction;

a curvature radius of the second curved surface decreases in a direction from a side of the second portion connected with the first portion to a side of the second portion away from the first portion.

In some embodiments of the present application, a curvature radius of the first curved surface is less than or equal to 1500 mm, and a minimum curvature radius of the second curved surface is greater than or equal to 3 mm.

In some embodiments of the present application, the cover plate further includes a second portion; in the first direction, the curvature radius of the first curved surface is constant, and the second portion is connected to opposite sides of the first portion, the first portion and the second portion are provided as a whole to cover the bending portion entirely, a side of the second portion facing the display panel is a second curved surface, and the second curved surface is connected to the first curved surface, wherein the maximum curvature radius of the second curved surface is less than or equal to the curvature radius of the first curved surface in the first direction;

wherein the curvature radius of the second curved surface decreases in a direction from a side of the second portion connected with the first portion to a side of the second portion away from the first portion;

in a two-dimensional coordinate system with the length of the second curved surface in the first direction as an X-axis and the curvature radius of the second curved surface as a Y-axis, the endpoint of the maximum curvature radius of the second curved surface is defined as the first endpoint (0, a), a>0, and the endpoint of the minimum curvature radius of the second curved surface is defined as the second endpoint (b, c), and b is a total length of the second curved surface in the first direction, c>0, and a straight line connects the first endpoint and the second endpoint;

wherein in the coordinate systems corresponding to curvature radius of the second curved surface, except the coordinates corresponding to the maximum curvature radius and the minimum curvature radius of the second curved surface, the coordinates corresponding to other curvature radius of the second curved surface are located on a side of the straight line away from the origin (0, 0).

In some embodiments of the present application, coordinates corresponding to curvature radius of the second curved surface are connected to define a curvature line, wherein the curvature line is a parabola.

In some embodiments of the present application, a length of the first portion is greater than a length of the second portion in the first direction.

In some embodiments of the present application, a curvature radius of the first curved surface is less than or equal to 1500 mm, and a minimum curvature radius of the second curved surface is greater than or equal to 50 mm.

In some embodiments of the present application, the cover plate further includes a third portion connected to a side of the second portion away from the first portion, a surface of the third portion facing the display panel is a third curved surface, and the third curved surface is connected to the second curved surface, wherein the maximum curvature radius of the third curved surface is less than or equal to the curvature radius of the second curved surface in the first direction;

wherein a curvature radius of the third curved surface decreases in a direction from a side of the third portion connected with the second portion to a side of the third portion away from the second portion.

In some embodiments of the present application, a minimum curvature radius of the third curved surface is greater than or equal to 3 mm.

In some embodiments of the present application, a curvature radius of the first curved surface is gradually changed in the first direction.

In some embodiments of the present application, a curvature radius of the first curved surface gradually increases in directions from both side edges of the first curved surface to a central axis of the first curved surface.

The embodiments of the present application also provide a display device, wherein the display device includes:
a display panel including a display main body, a bending portion, and a binding portion, wherein the binding portion is provided on a back of the display main body through the bending portion;
and a cover plate as mentioned above, the cover plate is attached to a display side of the display panel through an optical adhesive.

For example, the cover plate includes a first portion, the first portion covers at least a part on a front side of the bending portion, a side of the first portion facing the display panel is a first curved surface, wherein a curvature radius of any point of the first curved surface is greater than or equal to 300 mm in a first direction, and the first curved surface covers at least a middle area of the bending portion, and the first direction is a direction of a long axis of the bending portion.

In some embodiments of the present application, a curvature radius of the first curved surface is constant in the first direction, and the first portion is provided to cover the bending portion entirely.

In some embodiments of the present application, the cover plate further includes a second portion connected to opposite sides of the first portion in the first direction, a side of the second portion facing the display panel is a second curved surface, the second curved surface is connected to the first curved surface, wherein the maximum curvature radius of the second curved surface is less than or equal to the curvature radius of the first curved surface in the first direction;

wherein a curvature radius of the second curved surface decreases in a direction from a side of the second portion connected with the first portion to a side of the second portion away from the first portion.

In some embodiments of the present application, a curvature radius of the first curved surface is less than or equal to 1500 mm, and a minimum curvature radius of the second curved surface is greater than or equal to 3 mm.

In some embodiments of the present application, the cover plate further includes a second portion; in the first direction, the curvature radius of the first curved surface is constant, and the second portion is connected to opposite sides of the first portion, the first portion and the second portion are provided as a whole to cover the bending portion entirely, a side of the second portion facing the display panel is a second curved surface, and the second curved surface is connected to the first curved surface, wherein the maximum curvature radius of the second curved surface is less than or equal to the curvature radius of the first curved surface in the first direction;

wherein the curvature radius of the second curved surface decreases in a direction from a side of the second portion connected with the first portion to a side of the second portion away from the first portion;

in a two-dimensional coordinate system with the length of the second curved surface in the first direction as an X-axis and the curvature radius of the second curved surface as a Y-axis, the endpoint of the maximum curvature radius of the second curved surface is defined as the first endpoint (0, a), a>0, and the endpoint of the minimum curvature radius of the second curved surface is defined as the second endpoint (b, c), and b is a total length of the second curved surface in the first direction, c>0, and a straight line connects the first endpoint and the second endpoint;

wherein in the coordinate systems corresponding to curvature radius of the second curved surface, except the coordinates corresponding to the maximum curvature radius and the minimum curvature radius of the second curved surface, the coordinates corresponding to other curvature radius of the second curved surface are located on a side of the straight line away from the origin (0, 0).

In some embodiments of the present application, coordinates corresponding to curvature radius of the second curved surface are connected to define a curvature line, wherein the curvature line is a parabola.

In some embodiments of the present application, a length of the first portion is greater than a length of the second portion in the first direction.

In some embodiments of the present application, a curvature radius of the first curved surface is less than or equal to 1500 mm, and a minimum curvature radius of the second curved surface is greater than or equal to 50 mm.

In some embodiments of the present application, the cover plate further includes a third portion connected to a side of the second portion away from the first portion, a side of the third portion facing the display panel is a third curved surface, the third curved surface is connected to the second curved surface, wherein, in the first direction, a maximum curvature radius of the third curved surface is less than or equal to a curvature radius of the second curved surface;

the curvature radius of the third curved surface decreases in a direction from a side of the third portion connected with the second portion to a side of the third portion away from the second portion.

In some embodiments of the present application, the minimum curvature radius of the third curved surface is greater than or equal to 3 mm.

In some embodiments of the present application, the curvature radius of the first curved surface is gradually changed in the first direction.

In some embodiments of the present application, the curvature radius of the first curved surface gradually increases in directions from both side edges of the first curved surface to the central axis of the first curved surface.

### Beneficial Effect

According to the embodiments of the present application, a cover plate is attached to a display panel including a display main body, a bending portion, and a binding portion. The binding portion is provided on a back of the display main body through the bending portion. The cover plate includes a first portion covered at least a part of a front side of the bending portion. A side of the first portion facing the display panel is defined as a first curved surface. A curvature radius of any point of the first curved surface is greater than or equal to 300 mm in a first direction, and the first curved surface covers at least a middle area of the bending portion. The first direction is a direction of a long axis of the bending portion.

The cover plate of the embodiments of the present application adopts the first portion with large curvature radius to cover on a front side of the bending part, so that the bending stress on a part of the bending portion corresponding to the cover plate is reduced, thereby reducing the risk of breakage of wrings in the bending portion.

### BRIEF DESCRIPTION OF THE DRAWINGS

FIG. 1 is a schematic diagram of a display module provided in the existing art;

FIG. 2 is a schematic bottom view of a display device according to some embodiments of the present application;

FIG. 3 is a schematic cross-sectional view along line AA of FIG. 2;

FIG. 4 is an enlarged view of part C1 in FIG. 3;

FIG. 5 is a schematic cross-sectional view along the line BB of FIG. 2;

FIG. 6 is an enlarged view of part C2 in FIG. 5;

FIG. 7 is a schematic cross-sectional view along the line CC in FIG. 2;

FIG. 8 is a schematic bottom view of a cover plate of a display device according to some embodiments of the present application;

FIG. 9 is a schematic diagram of a cover plate of a display device according to some embodiments of the present application, from a first perspective;

FIG. 10 is a schematic diagram of a cover plate of a display device according to some embodiments of the present application, from a second perspective;

FIG. 11 is a schematic bottom view of another display device according to some embodiments of the present application;

FIG. 12 is a schematic cross-sectional view of FIG. 11 along the line CC;

FIG. 13 is a graph of curvature of a second curved surface in another display device according to some embodiments of the present application;

FIG. 14-1 is a simulation experiment diagram of Comparative Example 1;

FIG. 14-2 is a simulation experiment diagram of Comparative Example 2;

FIG. 15 is a schematic diagram of a cover plate of another display device according to some embodiments of the present application; and

FIG. 16 is a schematic diagram of another display device according to some embodiments of the present application.

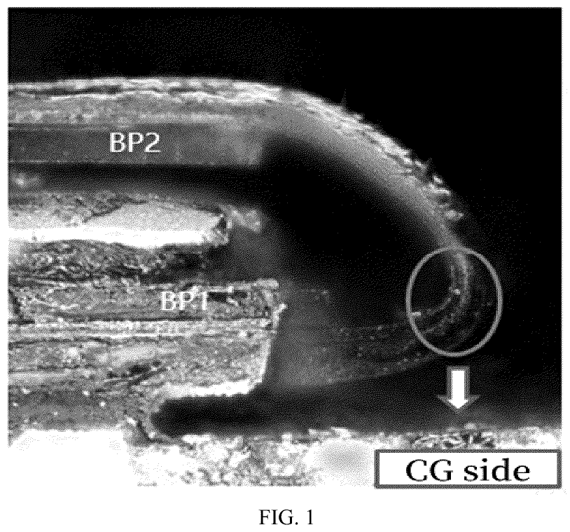

In FIG. 1, BP1 and BP2 are backplanes supporting the display panel.

### DETAILED DESCRIPTION

In the following, the technical solutions in the embodiments of the present application will be clearly and completely described in connection with the drawings in the embodiments of the present application. Obviously, the described embodiments are merely a part of the embodiments of the present application, rather than all the embodiments. Based on the embodiments in the present application, other embodiments obtained by those skilled in the art without involving any inventive effort are within the scope of the present application. Furthermore, it should be understood that the specific embodiments described herein are for purposes of illustration and explanation and are not intended to limit the application. In the present application, unless otherwise stated, directional words such as “up” and “down” usually refer to the up and down in the actual use or operating state of the device, specifically the drawing direction in the drawings; while “in” and “out” refer to the outline of the device; the terms “first”, “second” and “third” are only used as signs and do not impose numerical requirements or establish an order.

Some embodiments of the present application provide a cover plate and a display device, which are described in detail below. It should be noted that the order in which the following examples are described is not intended to limit the preferred order of the examples.

According to some embodiments of the present application, a cover plate a is attached to a display panel including a display main body, a bending portion, and a binding portion, wherein the binding portion is provided on a back of the display main body through the bending portion; the cover plate includes a first portion for covering at least a part on a front side of the bending portion; a side of the first portion facing the display panel is a first curved surface, wherein a curvature radius of any point of the first curved surface is greater than or equal to 300 mm in a first direction, and the first curved surface covers at least a middle area of the bending portion, and the first direction is a direction of a long axis of the bending portion.

According to the embodiments of the present application, the cover plate a adopts the first part with large curvature radius to cover the bending part on the front, which reduces the bending stress on the bending part corresponding to the cover plate, thus the risk of breakage of the wirings in the bending part is reduced.

The embodiments of the present application are described in detail below.

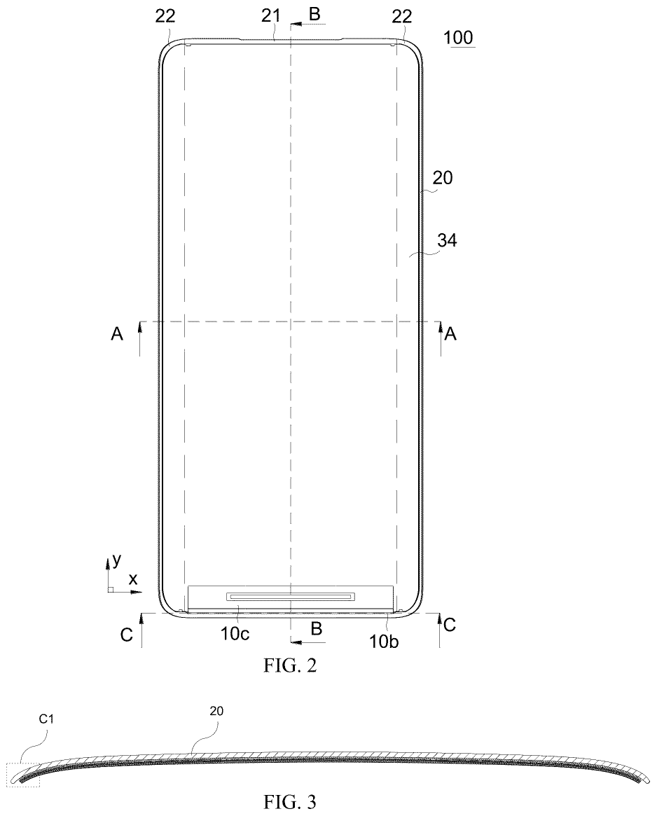

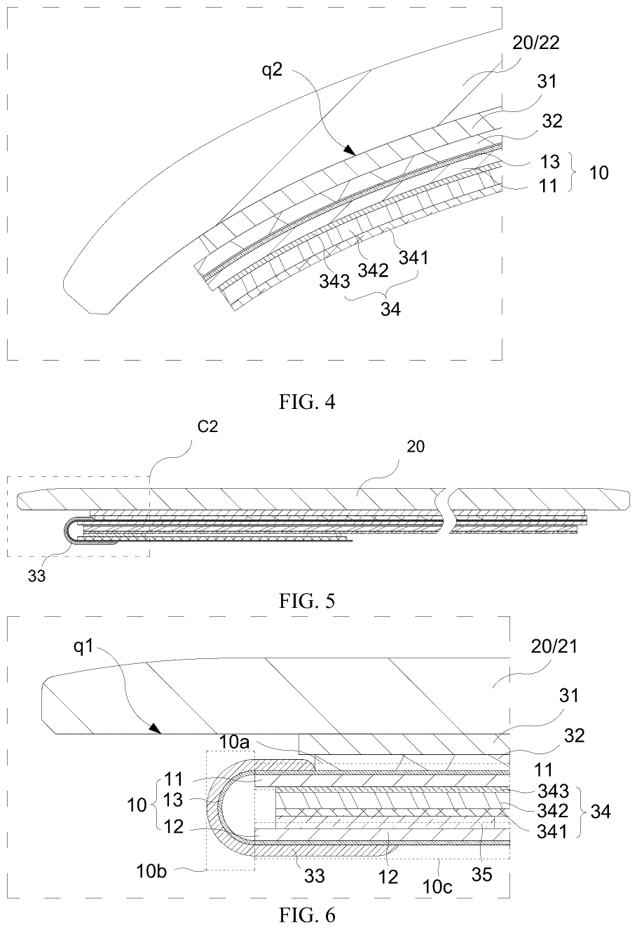

Referring to FIG. 2 to FIG. 7, some embodiments of the present application provide a display device 100 including a display panel 10 and a cover plate 20.

The display panel 10 includes a display main body 10a, a bending portion 10b, and a binding portion 10c provided on the back of the display main body 10a through the bending portion 10b. The cover plate 20 is attached to the display side of the display panel 10 by an optical adhesive 31.

In some embodiments of the present application, the display panel 10 includes a first backplane 11, a second backplane 12, and a display device layer 13 to define a stacked structure. The display device 100 may also include a polarizer 32, a protective layer 33, and a heat-dissipating stacked layer 34.

A part of the display device layer 13 corresponding to the display main body 10a is provided on the first backplane 11, a part of the display device layer 13 corresponding to the binding portion 10c is provided on the second backplane 12, and a part of the display device layer 13 corresponding to the bending portion 10b is bent.

The polarizer 32 is provided on the display device layer 13, and an optical adhesive 31 is provided on the polarizer 32. The second backplane 12 is disposed on the side of the first backplane 11 away from the cover plate 20.

The heat-dissipating stacked layer 34 is adhered between the first backplane 11 and the second backplane 12 by an adhesive layer 35. The heat-dissipating stacked layer 34 includes a heat-dissipating layer 341, a base layer 342, and a buffer layer 343 stacked in order.

The protective layer 33 covers the bending portion 10b, and extends to cover a part of the display main body 10a and a part of the binding portion 10c.

In some embodiments of the present application, the display device layer 13 may be an organic light-emitting display layer (OLED), a quantum dot light-emitting display layer (QLED), or a miniature inorganic light-emitting display layer (u-LED).

In some embodiments, the polarizer 32 may also be replaced with a color film layer integrated in the display device layer 13.

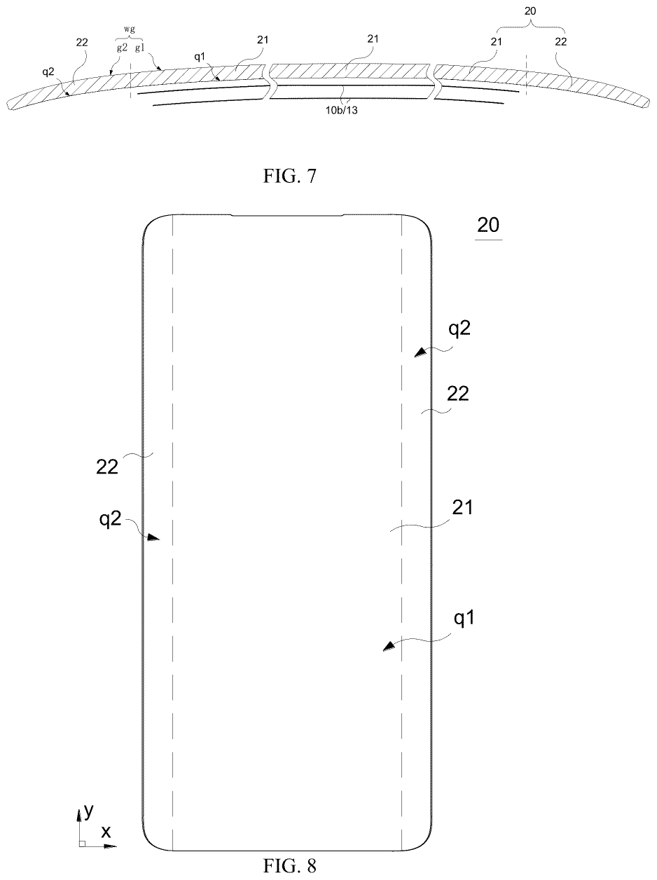

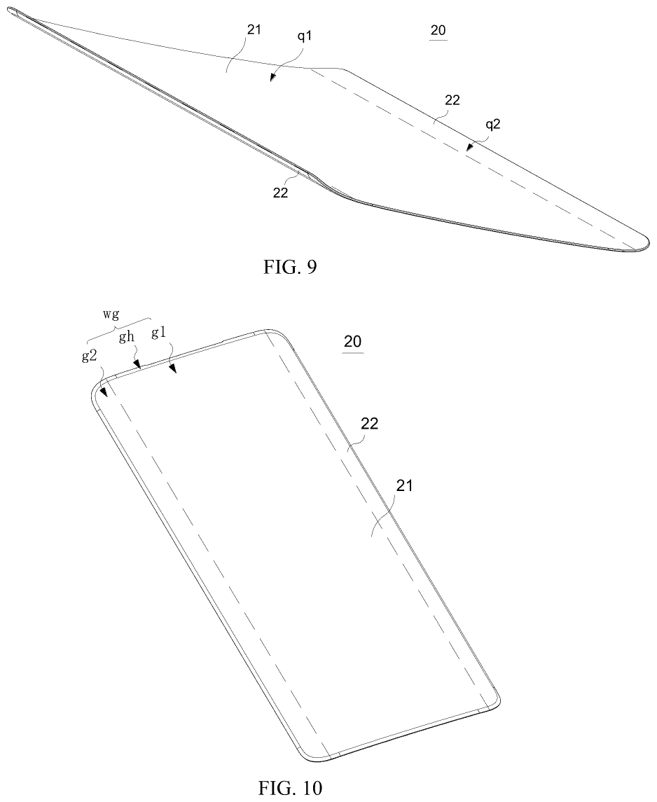

Referring to FIG. 7 to FIG. 9, the cover plate 20 includes a first portion 21 covered at least a part of the front side of the bending portion 10b; and a side of the first portion 21 facing the display panel 10 is defined as a first curved surface q1. In the first direction x, a curvature radius of the first curved surface q1 is constant. The curvature radius of the first curved surface q1 is greater than or equal to 300 mm. The first curved surface q1 covers at least the middle area of the bending portion 10b. The first direction x is a direction along which the long axis of the bending portion 10b is extended.

The cover plate 20 of the display device 100 according to the embodiments of the present application provides the first portion 21 having a large curvature radius to cover on the front side of the bending portion 10b, thereby reducing the bending stress on a part of the bending portion 10b corresponding to the cover plate 20, thereby reducing the risk of wire breakage in the bending portion 10b.

In some embodiments of the present application, the curvature radius of the first curved surface q1 may be 300 mm, 350 mm, 400 mm, 450 mm, 500 mm, 550 mm, 600 mm, 650 mm, 700 mm, 750 mm, 800 mm, 850 mm, 900 mm, 950 mm, 1000 mm, 1050 mm, 1100 mm, 1150 mm, 1200 mm, 1250 mm, 1300 mm, 1350 mm, 1400 mm, 1450 mm, 1500 mm, 1550 mm, 1600 mm, 1650 mm, 1700 mm, 1750 mm, 1800 mm, 1850 mm, 1900 mm, 1950 mm, or 2000 mm, etc.

It should be understood that the greater the curvature radius of the first portion 21 of the cover plate 20, the less influence from the cover plate 20 on the bending stress on the bending portion 10b, and the less breakage of the wirings of the bending portion 10b.

Therefore, the first portion with a curvature radius greater than or equal to 300 mm at least corresponds to the middle area of the bending portion 10b, so that the bending stress on the bending portion 10b is reduced, thereby reducing the risk of breakage of the wirings in the bending portion 10b.

In some embodiments of the present application, the first portion 21 covers the bending portion 10b entirely. In some embodiments, the first portion 21 with a large curvature radius covers the bending portion 10b entirely, so that the influence from the first portion 21 on the bending stress on the bending portion 10b may be minimized, thereby maximizing the protection of the wirings in the bending portion 10b.

The first portion 21 extends to cover a part of the display main body 10a. That is, the first curved surface q1 of the first portion 21 also extends to cover a part of the display body 10a.

In some embodiments of the present application, the cover plate 20 may further comprise a second portion 22 connected to the opposite sides of the first portion 21 in a first direction x. A side of the second portion 22 facing the display panel 10 is a second curved surface q2. The second curved surface q2 is connected to the first curved surface q1. The curvature radius of the second curved surface q2 decreases in the direction from a side of the second portion 22 connected with the first portion 21 to a side of the second portion 22 away from the first portion 21.

In the first direction x, a maximum value of the curvature radius of the second curved surface q2 is less than or equal to the curvature radius of the first curved surface q1.

In this embodiment, the second portion 22 with decreasing curvature radius is located at the opposite sides of the first portion 21to narrow the side of the cover plate 20, and it is suitable for the user to hold the display device, which makes the user more comfortable on holding.

In some embodiments of the present application, the curvature radius of the first curved surface q1 is less than or equal to 1500 mm. The minimum value of the curvature radius of the second curved surface q2 is greater than or equal to 3 mm.

For example, the minimum curvature radius of the second curved surface q2 may be 3 mm, 5 mm, 10 mm, 20 mm, 30 mm, 40 mm, 50 mm, 60 mm, 70 mm, 80 mm, 90 mm, 100 mm, 110 mm, 120 mm, 130 mm, 140 mm, 150 mm, 160 mm, 170 mm, 180 mm, 190 mm, or 200 mm.

It should be understood, in case that the curvature radius of the first curved surface q1 is greater than 1500 mm, for a small-sized display device 100, the display surface of the display device 100 tends to a flatted surface and fails to provide a curved screen. Therefore, the curvature radius of the first curved surface is selected to be less than or equal to 1500 mm to realize the curved screen.

Since the edge area of the display device 100 is in a contracted narrow-edge state, in a case that the minimum curvature radius of the second curved surface q2 is too small, a long size is required between the first curved surface and the second curved surface to transition, which is not conducive to the narrow edge. Moreover, an excessively small curvature radius is not suitable for the palm, resulting in a poor grip. Therefore, the minimum curvature radius of the second curved surface q2 is selected to be greater than or equal to 3 mm, so as to ensure that the edge area of the display device 100 meets the requirement of a narrow edge, and to improve the user's grip experience.

The maximum curvature radius of the second curved surface q2 is less than or equal to the curvature radius of the first curved surface q1, so that the first curved surface q1 can transition to the second curved surface q2 more gently and quickly, and the unsmooth of transition is reduced.

In some embodiments, in the first direction x, the curvature radius of the second curved surface q2 may also be constant, and the curvature radius of the second curved surface q2 is less than the curvature radius of the first curved surface q1.

Referring to FIG. 10, In some embodiments of the present application, the cover plate 20 further includes an appearance curved surface wg facing the user. The appearance curved surface wg includes a first appearance curved surface g1 of the first portion 21 and a second appearance curved surface g2 of the second portion 22, the first appearance curved surface g1 is disposed opposite to the first surface q1, and the second appearance curved surface g2 is disposed opposite to the second surface q2.

In the first direction x, the second appearance curved surface g2 is connected to the opposite sides of the first appearance curved surface g1. In the first direction x, the curvature radius of the first appearance curved surface g1 is equal to the curvature radius of the first surface q1 with which the first appearance curved surface g1 overlaps, and a curvature radius of the second appearance curved surface g2 is equal to a curvature radius of the second surface q2 with which the second appearance curved surface g2 overlaps.

In some embodiments of the present application, the appearance curved surface wg further includes an annular surface gh connected to the outer periphery of the structure defined by the first appearance curved surface g1 and the second appearance curved surface g2. The annular surface gh is a surface with chamfered arc.

The annular surface gh extends beyond the peripheral edges of the display panel 10. The annular surface gh on the long side is disposed opposite to and overlapped with the second curved surface q2, and the annular surface gh on the short side is disposed opposite to and overlapped with the first curved surface q1.

Using the surface with chamfered arc as the annular surface gh makes the peripheral sides of the display device 100 more smooth, thereby improving the grip and appearance.

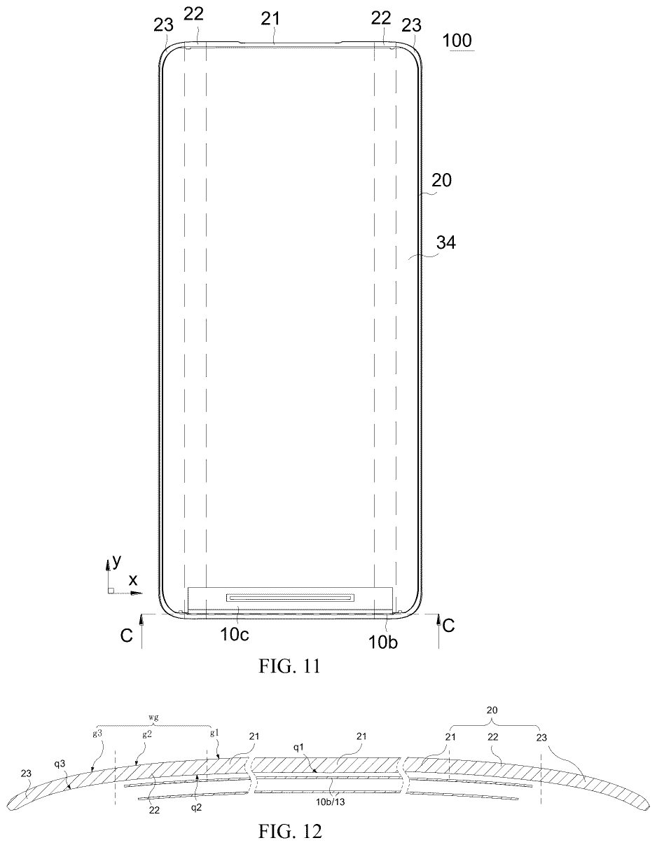

Referring to FIG. 11 to FIG. 12, the cover plate 20 of the display device 100 of another embodiment of the present application differs from the above-described embodiment in that the cover plate 20 is different in structure.

The cover plate 20 further includes a second portion 22 connected to opposite sides of the first portion 21 in the first direction x. The first portion 21 and the second portion 22 cover the bending portion 10b entirely as a whole. A side of the second portion 22 facing the display panel 10 is a second curved surface q2, which is connected to the first curved surface q1. Wherein the curvature radius of the second curved surface q2 decreases in the direction from a side of the second portion 22 connected with the first portion 21 to a side of the second portion 22 away from the first portion 21.

In the first direction x, a maximum curvature radius of the second curved surface q2 is less than or equal to a curvature radius of the first curved surface q1.

In order to further narrow the bezel and to make it more smooth, a second portion 22 with a gradient curvature radius is used to cover the side area of the bend 10b.

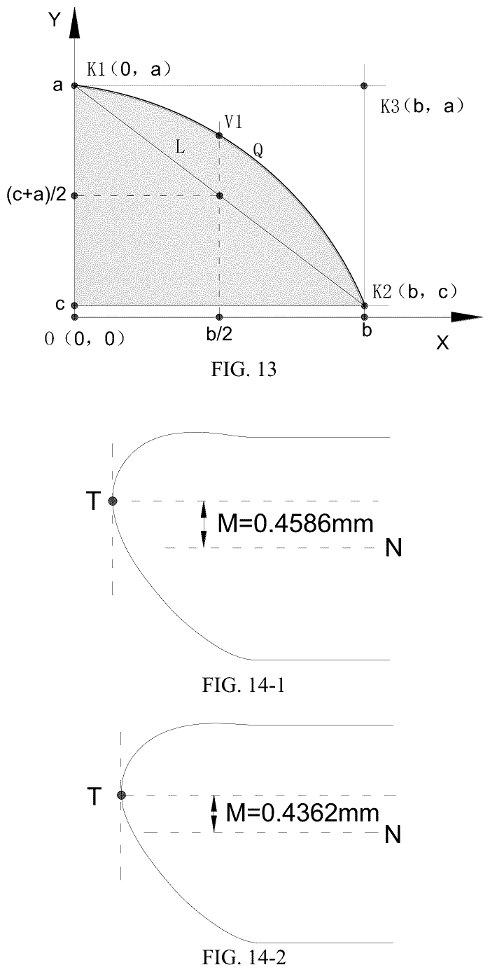

As shown in FIG. 13, in a two-dimensional coordinate system, the length of the second curved surface q2 in the first direction x represents an X-axis, and the curvature radius of the second curved surface q2 represents a Y-axis. The endpoint of the maximum curvature radius of the second curved surface q2 is defined as a first endpoint K1 (0, a), a>0, and the maximum curvature radius of the second curved surface q2 is equal to the curvature radius of the first curved surface q1. The endpoint of the minimum curvature radius of the second curved surface q2 is defined as a second endpoint K2 (b, c), where b is a total length of the second curved surface q2 in the first direction x, and c>0. A straight line L connects the first endpoint K1 and the second endpoint K2. The origin (0, 0) may be located on the intersection axis of the first curved surface q1 and the second curved surface q2.

In coordinate system corresponding to curvature radius of the second curved surface q2, except the coordinates corresponding to the maximum curvature radius and the minimum curvature radius of the second curved surface q2, the coordinate corresponding to other curvature radius of the second curved surface q2 are all located on a side of the straight line L away from the origin (0, 0).

In this embodiment, except for the coordinates corresponding to the maximum curvature radius and the minimum curvature radius of the second curved surface q2, the coordinates corresponding to the other curvature radius of the second curved surface q2 are located on a side of the straight line L away from the origin (0, 0), so that the curvature radius of the second curved surface q2 is avoided from a sharp decrease, thereby avoiding a sudden sharp increase in the stress effect on the bending portion 10b, thereby greatly reducing the risk of the wire breakage in the bending portion 10b.

It should be noted that the third endpoint K3 is defined to have a value b corresponding to the X-axis and a value a corresponding to the Y-axis. That is, the line connected with the first endpoint K1 and the third endpoint K3 is an iso-curvature line having the maximum curvature radius of the second curved surface q2 as the curvature radius.

According to the first endpoint K1 (0, a) and the second endpoint K2 (b, c), it may be seen that the straight line L is satisfied with Y_{L}=[(c−a)/b]X₁+a. Then, in case that X₁ is the same, the curvature radius between the first endpoint k1 and the second endpoint k2 in the second curved surface q2 is greater than Y_{L}.

For example, X₁ is b/2, then Y_{L}=(c+a)/2. The curvature radius of the center V1 of the second curved surface q2 is then greater than half of the sum of the maximum curvature radius and the minimum curvature radius of the second curved surface q2.

In the rectangle having the origin O, the first endpoint K1, the second endpoint K2, and the third endpoint K3 as the vertices, the area (gray portion) enclosed by the curvature line Q of the second curved surface q2, the straight line of Y=c and the Y-axis is closer to the area of the rectangle (the area enclosed by the iso-curvature line K1K3, the straight line of Y=c and the straight line of X=b), and the risk of breakage of the wirings in the bending portion 10b is reduced. A parameter of the curvature line Q corresponding to the Y-axis is a curvature radius.

For example, in the simulation experiment of Comparative Example 1, in a case that the curvature radius of the first curved surface q1 is 600 mm, and the curvature radius of the second curved surface q2 is 200 mm, the stress on the bending portion 10 b and the amount of upward warping are shown in FIG. 14-1.

In Comparative Example 2, in case that the curvature radius of the first curved surface q1 is 600 mm, and the curvature radius of the second curved surface q2 is 500 mm, the stress on the bending portion 10b and the amount of upward warping are shown in FIG. 14-2.

Where, the amount of upward warping M is the distance between the outer arc convex point T and the central axis N of the bending portion. The central axis N is a median line between the upper end and the lower end of the bending portion. The greater the amount of upward warping M, the greater the bending stress on the bending portion, and the greater the risk of breakage of wirings in the bending portion.

As can be seen from FIG. 14-1, the amount of upward warping M of Comparative Example 1 is 0.4586 mm. As can be seen from FIG. 14-2, the amount of upward warping M of Comparative Example 2 is 0.4362 mm. It is evident that the amount of upward warping of Comparative Example 1 is greater than the amount of upward warping of Comparative Example 2, and therefore the risk of breakage of wirings in the bend in Comparative Example 2 is lower.

Therefore, the lower the curvature line Q is, the lower the risk of breakage of the wirings in the bending portion 10b is.

In some embodiments of the present application, coordinates corresponding to curvature radius of the second curved surface q2 are connected to define a curvature line Q, the curvature line Q of the second curved surface q2 satisfies a unary quadratic function, and the curvature line Q is a parabola.

In some embodiments, the curvature line Q may also be a non-parabola, such as a multi-segment line, a curve segment with a diagonal segment, a connection of a plurality of arc segments, and so on.

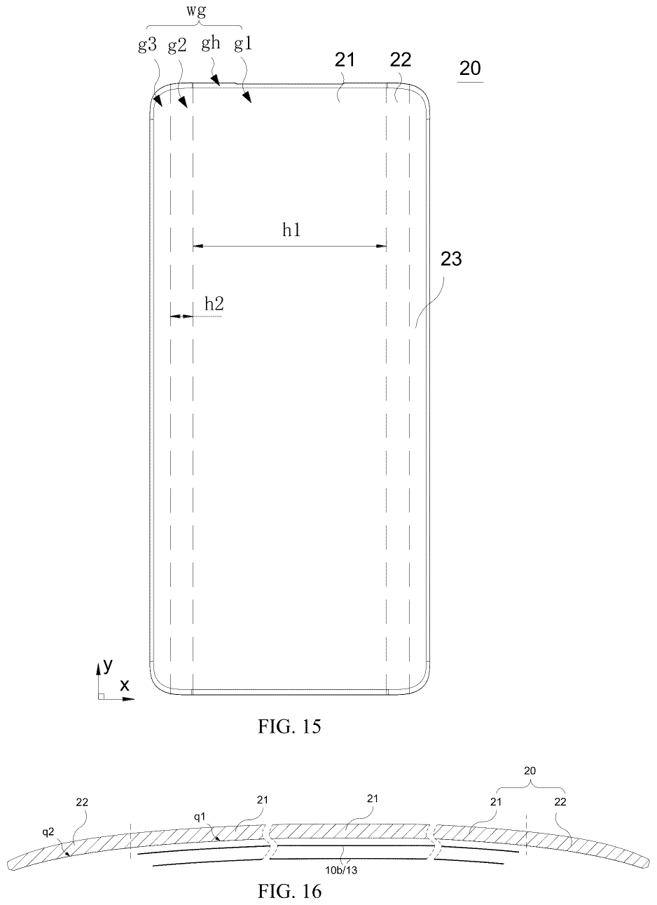

Referring to FIG. 15, In some embodiments of the present application, in the first direction x, the length h1 of the first portion 21 is greater than the length h2 of the second portion 22.

In some embodiments of the present application, the sum of the length h1 of the first portion 21 and the length h2 of the two second portions 22 is the total length. The length h2 of the second portion 22 is 4% to 10% of the total length, for example, it may be 4%, 5%, 6%, 7%, 8%, 9% or 10%. The length h1 of the first portion 21 is 80% to 92% of the total length, for example, it may be 80%, 81%, 82%, 83%, 84%, 85%, 86%, 87%, 88%, 89%, 90%, 91% or 92%.

It should be understood that since the curvature radius of the first curved surface q1 of the first portion 21 is greater than the curvature radius of the second curved surface q2 of the second portion 22, Therefore, under the same total length, the longer the length of the first portion 21 and the shorter the length of the second portion 22, the lower the risk of breakage of the wirings in the bending portion 10b.

In addition, the greater the length of the second portion 22, the greater the bending stress on a corresponding portion of the bending portion 10b, and the greater requirement on the bezel of the display device 100. The less the length of the second portion 22, the more difficult to chamfer the cover plate 20. Therefore, in order to reduce the risk of breakage of the wirings in the bending portion 10b, and meet the requirements of narrow bezel and chamfer, the length h2 of the single second portion 22 is designed to be 4% to 10% of the total length.

In some embodiments of the present application, the curvature radius of the first curved surface q1 is less than or equal to 1500 mm. The maximum curvature radius of the second curved surface q2 is less than or equal to the curvature radius of the first curved surface q1, and the minimum curvature radius of the second curved surface q2 is greater than or equal to 50 mm.

For example, the minimum curvature radius of the second curved surface q2 may be 50 mm, 60 mm, 70 mm, 80 mm, 90 mm, 100 mm, 110 mm, 120 mm, 130 mm, 140 mm, 150 mm, 160 mm, 170 mm, 180 mm, 190 mm, or 200 mm.

The minimum curvature radius of the second curved surface q2 is not less than 50 mm to protect the wiring of the bending portion 10 b.

It should be understood, in case that the curvature radius of the first curved surface q1 is greater than 1500 mm, for the small-sized display device 100, the display surface of the display device 100 attends to be a flatted surface and t fails to obtain a curved screen. Therefore, the curvature radius of the first curved surface is selected to be less than or equal to 1500 mm, so as to realize the curved screen.

Since the edge area of the display device 100 is in a contracted narrow-edge state, in a case that the minimum curvature radius of the second curved surface q2 is too small, it needs a long size to transition, which is not conducive to the narrow-edge. Moreover, if the arc length of the second curved surface q2 is longer, the bending stress on the corresponding bending part 10b will be greater. Therefore, the minimum curvature radius of the second curved surface q2 is selected to be greater than or equal to 50 mm, so as to ensure the safety of the wiring in the bending part 10 b and meet the requirements of the narrow-edge of the edge area of the display device 100.

The maximum curvature radius of the second curved surface q2 is less than or equal to the curvature radius of the first curved surface q1, so that the first curved surface q1 can transition to the second curved surface q2 more gently and quickly, so as to reduce the sense of abutment of the transition.

In some embodiments of the present application, the cover plate 20 further includes a third portion 23 connected to the side of the second portion 22 away from the first portion 21. A side of the third portion 23 facing the display panel 10 is a third curved surface q3, and the third curved surface q3 is connected to the second curved surface q2. In the first direction x, the curvature radius of the third curved surface q3 is less than or equal to the curvature radius of the second curved surface q2.

The curvature radius of the third curved surface q3 decreases in a direction from a side of the third portion 23 connected with the second portion 22 to a side of the third portion 23 away from the second portion 22.

This embodiment adopts a third portion 23 with decreasing curvature radius located on a side of the second portion 22 away from the first portion 21, so that the side of the cover plate 20 is narrowed, and it is suitable for the user to hold the display device, which makes the user more comfortable on holding.

In some embodiments of the present application, the maximum curvature radius of the third curved surface q3 is less than the minimum curvature radius of the second curved surface q2, and the minimum curvature radius of the third curved surface q3 is greater than or equal to 3 mm.

For example, the minimum curvature radius of the third curved surface q3 may be 3 mm, 5 mm, 10 mm, 20 mm, 30 mm, or 40 mm.

Referring to FIG. 15, In some embodiments of the present application, the cover plate 20 further includes an appearance curved surface wg facing the user, the appearance curved surface wg including a first appearance curved surface g1 of the first portion 21, a second appearance curved surface g2 of the second portion 22, and a third appearance curved surface g3 of the third portion 23, the first appearance curved surface g1 is disposed opposite to the first surface q1, and the second appearance curved surface g2 is disposed opposite to the second surface q2, and the third appearance curved surface g3 is disposed opposite to the third surface q3.

The second appearance curved surface g2 is connected to the opposite side of the first appearance curved surface g1, and the third appearance curved surface g3 is connected to the side of the second appearance curved surface g2 away from the first appearance curved surface g1. In the first direction x, the curvature radius of the first appearance curved surface g1 is equal to the curvature radius of the first surface q1 overlapped therewith, the curvature radius of the second appearance curved surface g2 coincides with the curvature radius of the second surface q2 overlapped therewith, and the curvature radius of the third appearance curved surface g3 coincides with the curvature radius of the third surface q3 overlapped therewith.

In some embodiments of the present application, the appearance curved surface wg further includes an annular surface gh connected to the outer periphery of the structure defined by the first appearance curved surface g1, the second appearance curved surface g2, and the third appearance curved surface g3. The annular surface gh is a surface with chamfered arc.

The annular surface gh extends beyond the peripheral edges of the display panel 10. The annular surface gh on the long side is disposed opposite to and overlapped with the third curved surface q3, and the annular surface gh on the short side is disposed opposite to and overlapped with the first curved surface q1 and the second curved surface q2, respectively.

Using the surface with chamfered arc as the annular surface gh makes the peripheral side of the display device 100 more smooth, which can improve the grip and appearance.

Referring to FIG. 16, the cover plate 20 of the display device 100 of another embodiment of the present application differs from the above-described embodiment in that the cover plate 20 is different in structure.

In the first direction x, the curvature radius of the first curved surface q1 is gradually changed.

That is, in the present embodiment, the first curved surface q1 with a constant curvature radius of the cover plate 20 of the display device 100 of any one of the above-described embodiments is replaced with the first curved surface q1 with a gradual changed curvature radius, and other structures are similar or the same.

In some embodiments of the present application, the curvature radius of the first curved surface q1 gradually increases in a direction from a side edge of the first curved surface q1 to the central axis of the first curved surface q1. That is, the curvature radius of the first curved surface q1 gradually decreases in direction from the center of the first curved surface q1 to a side edge of the first curved surface q1.

It should be noted that the curvature radius of the first curved surface q1 may be gradual changed in another way, which may be set according to the actual needs. The details are not repeated here.

Referring to FIG. 2 to FIG. 16, the embodiments of the present application further provide a cover plate 20 to attach to a display panel 10. The display panel 10 includes a display main body 10a, a bending portion 10b, and a binding portion 10c. The binding portion 10c is provided on a back of the display main body 10a by the bending portion 10b.

The cover plate 20 includes a first portion 21 for covering at least a part of the bend 10b on a front side. A side of the first portion 21 facing the display panel 10 is a first curved surface q1. In the first direction x, the curvature radius of any point of the first curved surface q1 is greater than or equal to 300 mm, and the first curved surface q1 is used to cover at least the middle area of the bending portion, and the first direction x is the long-axis direction of the bending portion 10b.

The structure of the cover plate 20 according to the embodiments of the present application is similar to or the same as that of the cover plate 20 of the display device 100 of the above-described embodiments, and details are not described herein.

A cover plate and a display device according to the embodiments of the present application are described in detail above, in which specific examples are used to explain the principles and embodiments of the present application. The description of the above embodiments is merely provided to help understand the method of the present application and the core idea thereof. At the same time, according to the idea of this application, the specific implementation and application scope may be changed by those skilled in the art. In view of the foregoing, the description should not be construed as limiting the application.

1. A cover plate, wherein the cover plate is provided to attach to a display panel; the display panel comprises a display main body, a bending portion, and a binding portion; and the binding portion is provided on a back of the display main body through the bending portion;
wherein the cover plate comprises a first portion provided to cover at least a part on a front side of the bending portion; and a side of the first portion facing the display panel is a first curved surface; wherein a curvature radius of any point of the first curved surface is greater than or equal to 300 mm in a first direction, the first curved surface covers at least a middle area of the bending portion, and the first direction is a direction of a long axis of the bending portion.

2. The cover plate of claim 1, wherein the curvature radius of the first curved surface is constant in the first direction, and the first portion is provided to cover the bending portion entirely.

3. The cover plate of claim 2, wherein the cover plate further comprises a second portion connected to opposite sides of the first portion in the first direction, a side of the second portion facing the display panel is a second curved surface, and the second curved surface is connected to the first curved surface, wherein a curvature radius of the second curved surface decreases in a direction from a side of the second portion connected with the first portion to a side of the second portion away from the first portion; and
a maximum curvature radius of the second curved surface is less than or equal to the curvature radius of the first curved surface in the first direction.

4. The cover plate of claim 3, wherein the curvature radius of the first curved surface is less than or equal to 1500 mm, and a minimum curvature radius of the second curved surface is greater than or equal to 3 mm.

5. The cover plate of claim 1, wherein the cover plate further comprises a second portion; in the first direction, the curvature radius of the first curved surface is constant, and the second portion is connected to opposite sides of the first portion, the first portion and the second portion are provided as a whole to cover the bending portion entirely, a side of the second portion facing the display panel is a second curved surface, and the second curved surface is connected to the first curved surface, wherein a curvature radius of the second curved surface decreases in a direction from a side of the second portion connected with the first portion to a side of the second portion away from the first portion; and
a maximum curvature radius of the second curved surface is less than or equal to the curvature radius of the first curved surface in the first direction;
in a two-dimensional coordinate system with a length of the second curved surface in the first direction as an X-axis and the curvature radius of the second curved surface as a Y-axis, an endpoint of the maximum curvature radius of the second curved surface is defined as a first endpoint (0, a), a>0; an endpoint of a minimum curvature radius of the second curved surface is defined as the second endpoint (b, c), wherein b is a total length of the second curved surface in the first direction, c>0; and a straight line connects the first endpoint and the second endpoint;
wherein in the coordinate systems corresponding to curvature radius of the second curved surface, except coordinates corresponding to the maximum curvature radius and the minimum curvature radius of the second curved surface, coordinates corresponding to another curvature radius of the second curved surface are located on a side of the straight line away from an origin.

6. The cover plate of claim 5, wherein coordinates corresponding to curvature radius of the second curved surface are connected to define a curvature line, wherein the curvature line is a parabola.

7. The cover plate of claim 5, wherein a length of the first portion is greater than a length of the second portion in the first direction.

8. The cover plate of claim 5, wherein the curvature radius of the first curved surface is less than or equal to 1500 mm, and a minimum curvature radius of the second curved surface is greater than or equal to 50 mm.

9. The cover plate of claim 5, wherein the cover plate further comprises a third portion connected to a side of the second portion away from the first portion, a side of the third portion facing the display panel is a third curved surface, and the third curved surface is connected to the second curved surface, wherein a curvature radius of the third curved surface decreases in a direction from a side of the third portion connected with the second portion to a side of the third portion away from the second portion; and
a maximum curvature radius of the third curved surface is less than or equal to the curvature radius of the second curved surface in the first direction.

10. The cover plate of claim 9, wherein a minimum curvature radius of the third curved surface is greater than or equal to 3 mm.

11. The cover plate of claim 1, wherein the curvature radius of the first curved surface is gradually changed in the first direction.

12. The cover plate of claim 11, wherein the curvature radius of the first curved surface gradually increases in directions from a side edge of the first curved surface to a central axis of the first curved surface.

13. A display device, comprising:
a display panel, wherein the display panel comprises a display main body, a bending portion, and a binding portion, wherein the binding portion is provided on a back of the display main body through the bending portion;
a cover plate attached to a display side of the display panel through an optical adhesive, the cover plate comprises a first portion, the first portion covers at least a part on a front side of the bending portion, a side of the first portion facing the display panel is a first curved surface, wherein a curvature radius of any point of the first curved surface is greater than or equal to 300 mm in a first direction, the first curved surface covers at least a middle area of the bending portion, and the first direction is a direction of a long axis of the bending portion.

14. The display device of claim 13, wherein a curvature radius of the first curved surface is constant in the first direction, and the first portion is provided to cover the bending portion entirely.

15. The display device of claim 14, wherein the cover plate further comprises a second portion connected to opposite sides of the first portion in the first direction, a side of the second portion facing the display panel is a second curved surface, the second curved surface is connected to the first curved surface, wherein a curvature radius of the second curved surface decreases in a direction from a side of the second portion connected with the first portion to a side of the second portion away from the first portion; and
a maximum curvature radius of the second curved surface is less than or equal to the curvature radius of the first curved surface in the first direction.

16. The display device of claim 15, wherein the curvature radius of the first curved surface is less than or equal to 1500 mm, and a minimum curvature radius of the second curved surface is greater than or equal to 3 mm.

17. The display device of claim 13, wherein the cover plate further comprises a second portion; in the first direction, the curvature radius of the first curved surface is constant, and the second portion is connected to opposite sides of the first portion, the first portion and the second portion are provided as a whole to cover the bending portion entirely, a side of the second portion facing the display panel is a second curved surface, and the second curved surface is connected to the first curved surface, wherein a curvature radius of the second curved surface decreases in a direction from a side of the second portion connected with the first portion to a side of the second portion away from the first portion; and
a maximum curvature radius of the second curved surface is less than or equal to the curvature radius of the first curved surface in the first direction;
in a two-dimensional coordinate system with a length of the second curved surface in the first direction as an X-axis and the curvature radius of the second curved surface as a Y-axis, an endpoint of the maximum curvature radius of the second curved surface is defined as a first endpoint (0, a), a>0, an endpoint of a minimum curvature radius of the second curved surface is defined as the second endpoint (b, c), wherein b is a total length of the second curved surface in the first direction, c>0, and a straight line connects the first endpoint and the second endpoint;
wherein in the coordinate systems corresponding to curvature radius of the second curved surface, except coordinates corresponding to the maximum curvature radius and the minimum curvature radius of the second curved surface, coordinates corresponding to another curvature radius of the second curved surface are located on a side of the straight line away from an origin.

18. The display device of claim 17, wherein coordinates corresponding to curvature radius of the second curved surface are connected to define a curvature line, wherein the curvature line is a parabola.

19. The display device of claim 17, wherein a length of the first portion is greater than a length of the second portion in the first direction.

20. The display device of claim 17, wherein a curvature radius of the first curved surface is less than or equal to 1500 mm, and a minimum curvature radius of the second curved surface is greater than or equal to 50 mm.
